(19) United States
(12) Patent Application Publication
(10) Pub. No.: US 2011/0305067 A1
(43) Pub. Date: Dec. 15, 2011

(54) SEMICONDUCTOR MEMORY DEVICE IN WHICH RESISTANCE STATE OF MEMORY CELL IS CONTROLLABLE

(75) Inventor: Yoshihiro Ueda, Yokohama-shi (JP)

(73) Assignee: KABUSHIKI KAISHA TOSHIBA, Tokyo (JP)

(21) Appl. No.: 13/052,978

(22) Filed: Mar. 21, 2011

(30) Foreign Application Priority Data
Jun. 10, 2010 (JP) 2010-133138

(51) Int. Cl. G11C 11/21

(52) U.S. Cl. 365/148; 365/158

(57) ABSTRACT

According to one embodiment, a semiconductor memory device includes memory cells and sense amplifiers. One end of the memory cell is connected to each of bit lines. The other end of the memory cell is connected to a source line. The sense amplifiers are connected to the bit lines. First writing changes the resistance of the memory cells connected to a first state by a current running from the source line to the bit lines. Second writing changes the resistance of the memory cells to a second state by a current running from the bit lines to the source line on the basis of data retained by the sense amplifiers after the first writing. Before the first writing, data is read from the memory cells, and the read data is retained in the sense amplifiers, and the data retained by the sense amplifiers is overwritten in accordance with write data.

### CROSS-REFERENCE TO RELATED APPLICATIONS

This application is based upon and claims the benefit of priority from Japanese Patent Application No. 2010-133138, filed Jun. 10, 2010; the entire contents of which are incorporated herein by reference.

### FIELD

Embodiments described herein relate generally to a semiconductor memory device, such as a semiconductor memory device comprising a variable resistance element.

### BACKGROUND

Recently, a resistance change memory has been drawing attention as one semiconductor memory device. As the resistance change memory, there is known a magnetic random access memory (MRAM) that uses a spin-transfer torque magnetization reversal, or a phase-change random access memory (PRAM) that uses a resistance change between a crystalline state (conductor) and an amorphous state (insulator).

The MRAM, the PRAM, and ReRAM use variable resistance elements as memory cells, and record information, for example, by setting a low-resistance state as “0” and a high-resistance state as “1”. In connection with the PRAM, a writing method highly compatible with the DRAM has been suggested. In the PRAM, both “0” writing and “1” writing are performed by passing write currents in the same direction through a memory cell. On the other hand, in the MRAM and the ReRAM, “0” writing and “1” writing are performed by currents in different directions.

### BRIEF DESCRIPTION OF THE DRAWINGS

FIG. 1 is a circuit diagram showing the configuration of an MRAM according to a first embodiment;

FIG. 2 is a sectional view showing the configuration of an MTJ element according to the first embodiment;

FIGS. 3A and 3B are schematic diagrams showing the magnetization state of the MTJ element according to the first embodiment;

FIG. 4 is a diagram showing a write sequence and a read sequence in the MRAM according to the first embodiment;

FIG. 5 is a schematic diagram of part of the write sequence according to the first embodiment;

FIG. 6 is a schematic diagram of part of the read sequence according to the first embodiment;

FIGS. 7A and 7B are circuit diagrams showing the behavior of S/A operation according to the first embodiment;

FIG. 8 is a circuit diagram showing the behavior of S/A cache overwrite according to the first embodiment;

FIG. 9 is a circuit diagram showing the behavior of page erasing according to the first embodiment;

FIG. 10 is a circuit diagram showing the behavior of page writing according to the first embodiment;

FIG. 11 is a circuit diagram showing the behavior of S/A cache read according to the first embodiment; and

FIG. 12 is a circuit diagram showing the configuration of an MRAM according to a second embodiment.

### DETAILED DESCRIPTION

A semiconductor memory device according to embodiments will be described hereinafter with reference to the drawings. In the following explanation, like reference marks are assigned to like parts throughout the drawings, and repeated explanations are not given.

As a resistance change memory device according to the embodiments, it is possible to use various kinds of memories such as an MRAM and a resistive random access memory (ReRAM) in which bi-directional currents are passed through a memory cell to control the resistance state of the memory cell. In the present embodiment, the MRAM is described as an example of the resistance change memory. The MRAM comprises, as a storage element, a magnetic tunnel junction (MTJ) element that uses the magnetoresistive effect. The MRAM uses the magnetization arrangement of the MTJ element to store information.

In general, according to one embedment, a semiconductor memory device includes a cell array and sense amplifiers. The cell array includes memory cells. One end of each of the memory cells is connected to each of first bit lines. The other end of each of the memory cells is connected to a first source line. A gate terminal of each of the memory cells is connected to a word line. The sense amplifiers are connected to the first bit lines. The sense amplifiers read the memory cells and retain data. First writing changes the resistance of the memory cells connected to the word line to a first state by a current running from the first source line to the first bit lines. Second writing changes the resistance of the memory cells to a second state by a current running from the first bit lines to the first source line on the basis of data retained by the sense amplifiers after the first writing. Before the first writing, data is read from the memory cells, and the read data is retained in the sense amplifiers, and the data retained by the sense amplifiers is overwritten in accordance with write data.

### [1] First Embodiment

An MRAM according to the first embodiment is described below.

[1-1] Configuration According to First Embodiment

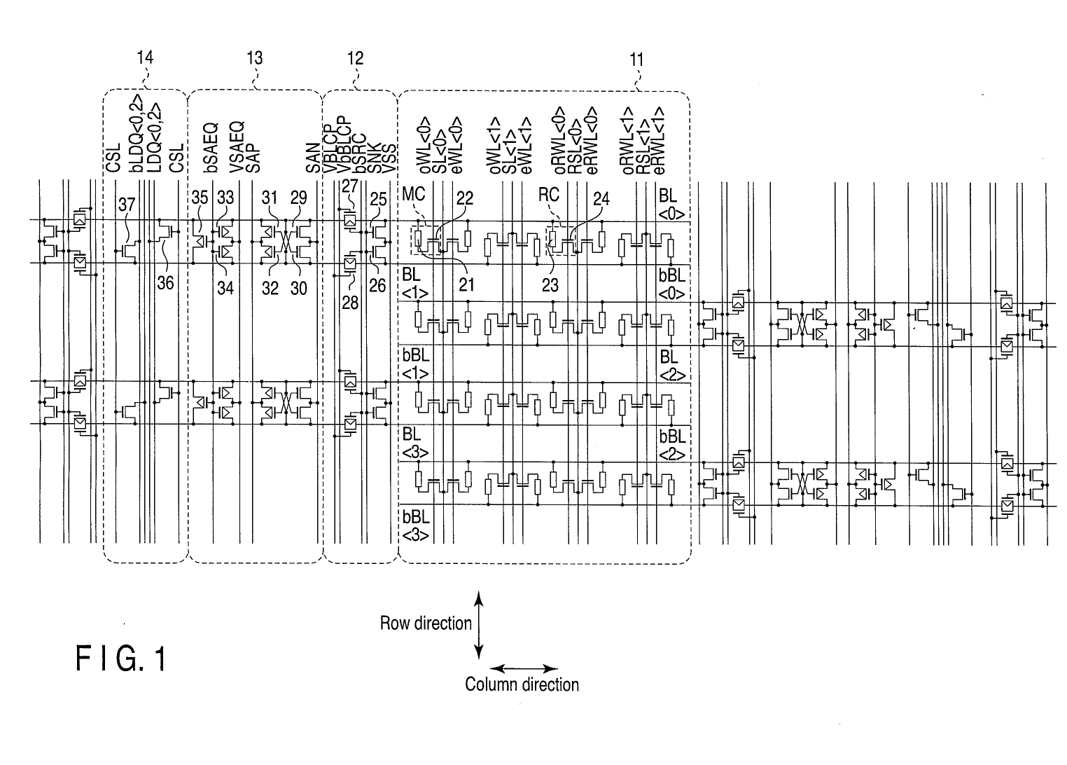

FIG. 1 is a circuit diagram showing the configuration of the MRAM according to the first embodiment.

As shown in FIG. 1, the MRAM comprises, for example, a cell array 11, a column gate and bit line clamper 12, a sense amplifier 13, and a column selection switch and data line 14.

In the cell array 11, pairs of bit lines BL<0>, BL<1>, BL<2>, BL<3> and complementary bit lines bBL<0>, bBL<1>, bBL<2>, bBL<3> extend parallel in a column direction. Moreover, source lines SL<0>, SL<1>, RSL<0>, RSL<1> and word lines oWL<0>, eWL<0>, oWL<1>, eWL<1>, oRWL<0>, eRWL<0>, oRWL<1>, eRWL<1> extend parallel in a row direction perpendicular to the column direction. In addition, the bit lines, the source lines, and the word lines are not limited in number, and more bit lines, source lines, and word lines are actually arranged than those illustrated in FIG. 1.

The cell array 11 comprises a memory cell MC and a reference cell RC. The memory cell MC comprises a variable resistance element 21 and a select transistor 22 that are connected in series between the bit line BL<0> and the source line SL<0>. The select transistor 22 comprises, for example, an n-channel MOS field effect transistor (hereinafter, nMOS transistor). The variable resistance element 21 will be described in detail later.

One end of the variable resistance element 21 is connected to the bit line BL<0>, and the other end of the variable resistance element 21 is connected to one end of a current path of the select transistor 22. The other end of the current path of the select transistor 22 is connected to the source line SL<0>. Moreover, a gate terminal of the select transistor 22 is connected to the word line oWL<0>. Thus, the memory cell MC is located at the intersection of the bit line, the source lines SL<0>, SL<1>, and the word lines oWL<0>, eWL<0>, oWL<1>, eWL<1>. As shown in FIG. 1, the memory cells MC are arranged in matrix form.

Although one end of the variable resistance element 21 is connected to the bit line and the other end of the current path of the select transistor 22 is connected to the source line SL<0> in the example shown, the present embodiment is not limited thereto. One end of the current path of the select transistor 22 may be connected to the bit line, and the other end of the variable resistance element 21 may be connected to the source line. Two memory cells MC may be arranged so that the source line SL is shared by the adjacent memory cells MC.

Furthermore, the reference cell RC comprises a resistance element 23 and a select transistor 24 that are connected in series between the bit line BL<0> and the source line RSL<0>. The select transistor 24 comprises, for example, an nMOS transistor. The resistance element 23 will be described in detail later.

One end of the resistance element 23 is connected to the bit line BL<0>, and the other end of the resistance element 23 is connected to one end of a current path of the select transistor 24. The other end of the current path of the select transistor 24 is connected to the source line RSL<0>. Moreover, a gate terminal of the select transistor 24 is connected to the word line oRWL<0>. Thus, the reference cell RC is located at the intersection of the bit line, the source lines RSL<0>, RSL<1>, and the word lines oRWL<0>, eRWL<0>, oRWL<1>, eRWL<1>. As shown in FIG. 1, the reference cells RC are arranged in matrix form.

One end of the current path of the select transistor 24 may be connected to the bit line, and the other end of the resistance element 23 may be connected to the source line. Two reference cells RC may be arranged so that the source line SL is shared by the adjacent reference cells RC.

Now, the column gate and bit line clamper 12, the sense amplifier 13, and the column selection switch and data line 14 are described.

The bit lines BL and the complementary bit lines bBL are connected to complementary input/output nodes of the sense amplifier 13 via the column gate and bit line clamper 12.

The column gate and bit line clamper 12 has two nMOS transistors 25 and 26 that constitute a bit line clamper, and two transfer gates 27 and 28 that constitute a column gate.

The bit line clamper comprises nMOS transistors 25 and 26, a power supply line Vss, and a signal line SNK. The bit line BL is connected to the drain of nMOS transistor 25, and the bit line bBL is connected to the drain of nMOS transistor 26. The power supply line Vss is connected to the sources of nMOS transistors 25 and 26. A reference voltage, for example, a ground voltage is supplied to the power supply line Vss. Signal line SNK is connected to the gates of nMOS transistors 25 and 26. The bit line clamper sets unselected bit lines to the ground voltage. Thus, a bit line adjacent to a selected bit line is always set at the ground voltage, such that stable read operation can be performed.

The column gate comprises the transfer gates 27 and 28, a signal line bSRC, a signal line VbBLCP, and a signal line VBLCP. The transfer gate 27 is connected to the bit line BL, and the transfer gate 28 is connected to the bit line bBL. Signal line bSRC is connected to the gates of p-channel MOS field effect transistors (hereinafter, pMOS transistors) that form the transfer gates 27 and 28, respectively. Signal line VbBLCP is connected to the gate of an nMOS transistor that forms the transfer gate 27. Further, signal line VBLCP is connected to the gate of an nMOS transistor that forms the transfer gate 28.

The sense amplifier 13 comprises nMOS transistors 29 and 30, pMOS transistors 31 and 32, a signal line SAN, a signal line SAP, pMOS transistors 33, 34, and 35, a power supply line VSAEQ, and a signal line bSAEQ.

The drain of nMOS transistor 29 is connected to the bit line BL, and the drain of nMOS transistor 30 is connected to the bit line bBL. Signal line SAN is connected to the sources of nMOS transistors 29 and 30.

The drain of pMOS transistor 31 is connected to the bit line BL, and the drain of pMOS transistor 32 is connected to the bit line bBL. Signal line SAP is connected to the sources of pMOS transistors 31 and 32.

The gate of nMOS transistor 29 is connected to the bit line bBL and the gate of pMOS transistor 31. Further, the gate of nMOS transistor 30 is connected to the bit line BL and the gate of pMOS transistor 32.

The drain of pMOS transistor 33 is connected to the bit line BL, and the drain of pMOS transistor 34 is connected to the bit line bBL. The power supply line VSAEQ is connected to the sources of pMOS transistors 33, 34. Moreover, signal line bSAEQ is connected to the gates of pMOS transistors 33, 34.

The drain of pMOS transistor 35 is connected to the bit line BL, and the source of pMOS transistor 35 is connected to the bit line bBL. Signal line bSAEQ is connected to the gate of pMOS transistor 35.

The sense amplifier 13 having such a configuration functions to retain read data and write data.

The column selection switch and data line 14 is connected to the sense amplifier 13. The input/output nodes of the sense amplifier 13 are connected to the data line via the column selection switch. The column selection switch and data line 14 comprises column select transistors (e.g., nMOS transistors) 36 and 37, column selection line CSL, and data lines LDQ and bLDQ.

The drain of the column select transistor 36 is connected to the bit line BL, and the source of the column select transistor 36 is connected to the data line LDQ. The gate of the column select transistor 36 is connected to the column selection line CSL. The drain of the column select transistor 37 is connected to the bit line bBL, and the source of the column select transistor 37 is connected to the data line bLDQ. The gate of the column select transistor 37 is connected to the column selection line CSL.

The column select transistors 36 and 37 are switched on/off under the control of the column selection line CSL. When the column select transistor 36 is on, the bit line BL is connected to the data line LDQ. When the column select transistor 37 is on, the bit line bBL is connected to the data line bLDQ.

The column gate and bit line clampers 12, the sense amplifiers 13, and the column selection switch and data lines 14 that are described above are alternately arranged on both sides of the cell array 11, as shown in FIG. 1.

[1-1-1] Configuration of Memory Cell

The memory cell MC comprises the variable resistance element 21 and the select transistor 22. The variable resistance element 21 and the select transistor 22 are connected in series between the bit line BL and the source line SL. The configuration of the variable resistance element 21 is described below. The variable resistance element 21 comprises, for example, a magnetoresistive element (MTJ element).

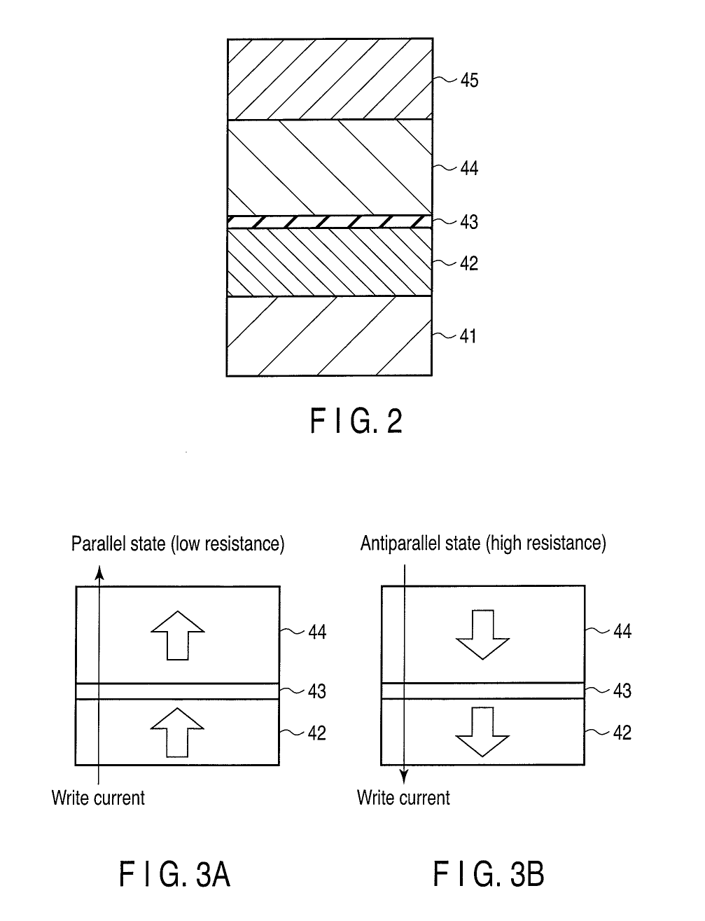

FIG. 2 is a sectional view showing the configuration of the MTJ element. The MTJ element has a structure in which a lower electrode 41, a recording layer (alternatively, a storage layer or a free layer) 42, a nonmagnetic layer 43, a reference layer (or a fixed layer) 44, and an upper electrode 45 are stacked in order. The stacking order may be reversed. The recording layer 42 and the reference layer 44 are made of ferromagnetic materials, respectively.

The recording layer 42 and the reference layer 44 have magnetic anisotropies perpendicular to a film plane, respectively. The directions of easy magnetization of the recording layer 42 and the reference layer 44 are perpendicular to the film plane. Alternatively, the magnetization directions of the recording layer 42 and the reference layer 44 may be parallel to the film plane.

The magnetization (or spin) direction of the recording layer 42 is variable (inverted). The magnetization direction of the reference layer 44 is invariable (fixed). The reference layer 44 is set to have sufficiently higher perpendicular magnetization anisotropic energy than the recording layer 42. The magnetic anisotropy can be set by adjusting material constitution and thickness. Thus, a magnetization reversal current for the recording layer 42 is lower, and a magnetization reversal current for the reference layer 44 is higher than that for the recording layer 42. As a result, it is possible to obtain an MTJ element that comprises the recording layer 42 variable in magnetization direction and the reference layer 44 invariable in magnetization direction for a predetermined write current.

FIGS. 3A and 3B are schematic diagrams showing the magnetization state of the MTJ element. According to a spin-transfer torque writing method used in the present embodiment, a write current is directly passed through the MTJ element, and the magnetization state of the MTJ element is controlled by this write current. The MTJ element can take one of the low-resistance state and the high-resistance state depending on whether the magnetizations of the recording layer 42 and the reference layer 44 are parallel or antiparallel.

As shown in FIG. 3A, if a write current directed from the recording layer 42 to the reference layer 44 is passed through the MTJ element, the magnetizations of the recording layer 42 and the reference layer 44 are parallel. In this parallel state, the resistance of the MTJ element is lowest, that is, the MTJ element is set to the low-resistance state. The low-resistance state of the MTJ element is determined as, for example, data “0”.

On the other hand, as shown in FIG. 3B, if a write current directed from the reference layer 44 to the recording layer 42 is passed through the MTJ element, the magnetizations of the recording layer 42 and the reference layer 44 are antiparallel. In this antiparallel state, the resistance of the MTJ element is highest, that is, the MTJ element is set to the high-resistance state. The high-resistance state of the MTJ element is determined as, for example, data “1”. Consequently, the MTJ element can be used as a storage element capable of storing one-bit data (binary data).

[1-1-2] Configuration of Reference Cell

The reference cell RC comprises the resistance element 23 and the select transistor 24. The resistance element 23 and the select transistor 24 are connected in series between the bit line BL and the source line RSL. The configuration of the resistance element 23 is described below. The resistance element 23 comprises, for example, a magnetoresistive element (MTJ element).

The resistance element 23 is used to generate a reference current serving as a standard for judging data in the memory cell MC. The resistance of the resistance element 23 is fixed. The resistance element 23 has, for example, a similar stack structure as the MTJ element shown in FIG. 2, and the magnetization of the recording layer 42 is also fixed similarly to that of the reference layer 44.

[1-2] Operation According to First Embodiment

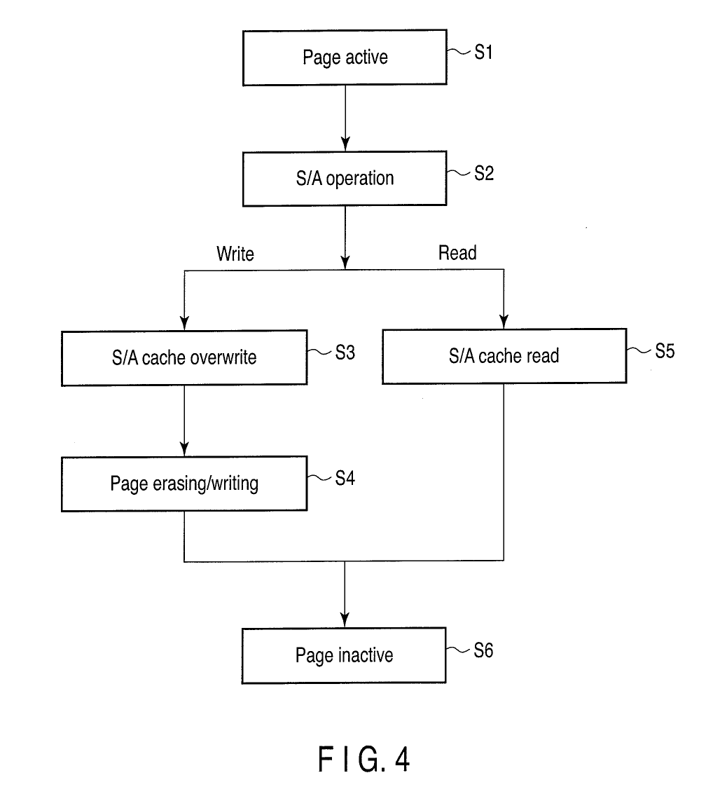

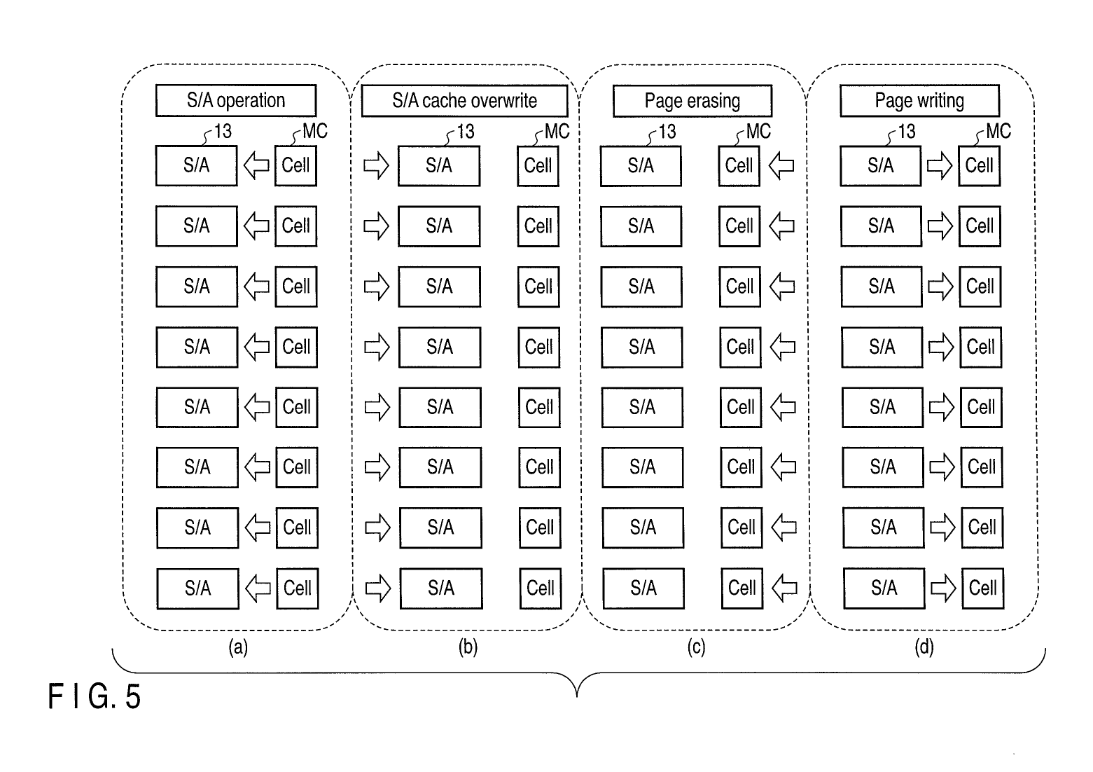

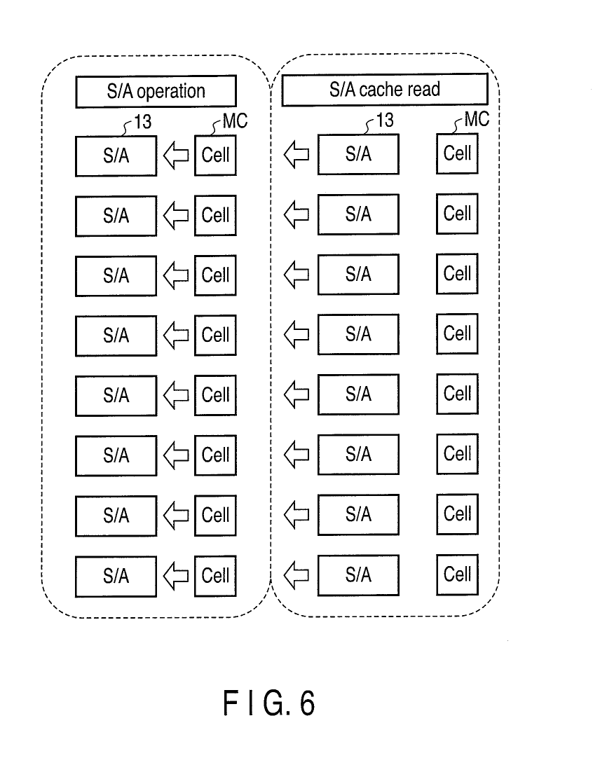

FIG. 4 is a diagram showing a write sequence and a read sequence in the MRAM according to the first embodiment. FIG. 5 shows a schematic diagram of part of the page writing sequence. FIG. 6 shows a schematic diagram of part of the page reading sequence. Writing and reading in the MRAM are performed page by page. A page comprises memory cells connected to the same word line.

In page active, the word line WL is activated, and the select transistors 22 of the memory cells MC connected to the word line are switched on (step S1).

In sense amplifier (S/A) operation, data is transferred to the sense amplifier 13 from the memory cell MC, as shown by (a) in FIG. 5. That is, a current is applied to the memory cell MC, and data stored in the memory cell MC is sensed, and then the data is retained in the sense amplifier 13 (step S2).

In S/A cache overwrite, data is written into the sense amplifier 13 from a peripheral circuit component, as shown by (b) in FIG. 5. That is, the data retained in the sense amplifier 13 is overwritten on the basis of the data input from the peripheral circuit component (step S3).

In page erasing, a current is passed to the memory cell MC from the source line SL, and the data stored in the memory cell MC is erased, as shown by (c) in FIG. 5. Further, in page writing, data is written into the memory cell MC from the sense amplifier 13, as shown by (d) in FIG. 5. That is, in the page erasing/writing, the resistance state (data) of the memory cells MC constituting a page is changed in accordance with the write data retained in the sense amplifier 13 (step S4). Here, erasing means writing “0” into the memory cell MC (first writing). Writing means writing “1” into the memory cell MC (second writing).

In S/A cache read, data is read into the peripheral circuit component from the sense amplifier 13, as shown in FIG. 6. That is, read data retained in the sense amplifier 13 is transferred to the peripheral circuit component (step S5).

In page inactive, the word line WL is inactivated, and the select transistors 22 of the memory cells MC connected to the word line are switched off (step S6).

The write sequence is performed in the order of the page active, the S/A operation, the S/A cache overwrite, the page erasing/writing, and the page inactive (step S1→S2→S3→S4→S6). The read sequence is performed in the order of the page active, the S/A operation, the S/A cache read, and the page inactive (step S1→S2→S5→S6).

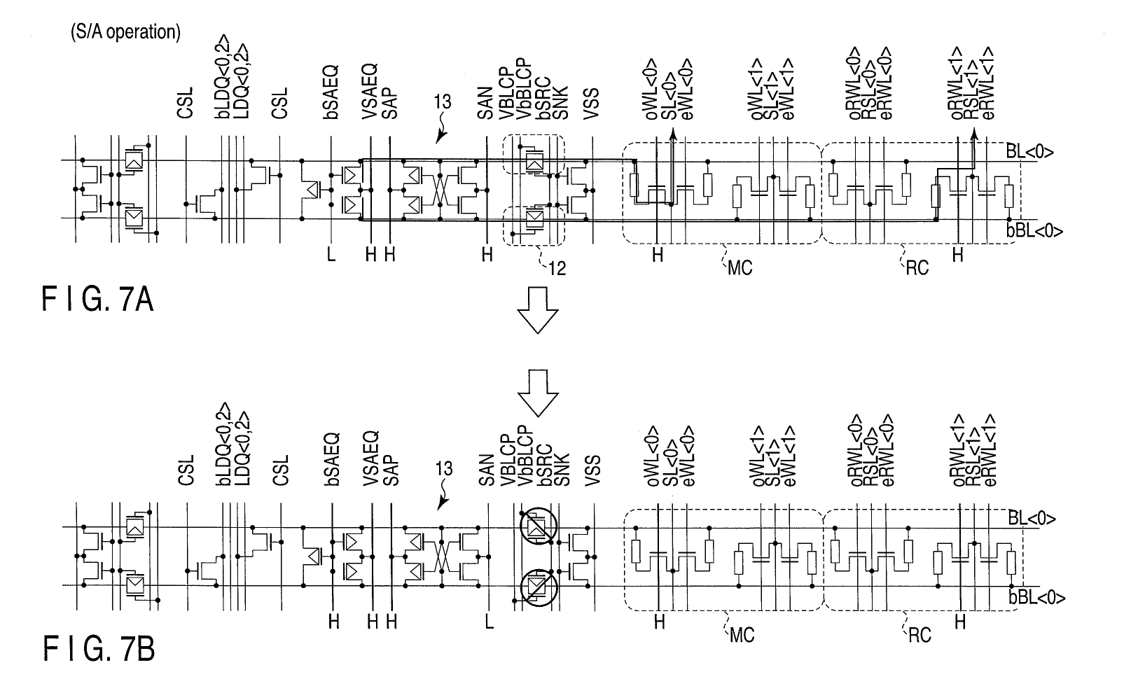

FIGS. 7A and 7B to FIG. 11 show the behaviors of the S/A operation, the S/A cache overwrite, the page erasing, the page writing, and the S/A cache read.

FIGS. 7A and 7B are circuit diagrams showing the behavior of the S/A operation. FIG. 7A shows a circuit diagram during the sensing by the sense amplifier 13, and FIG. 7B shows a circuit diagram after the end of the sensing by the sense amplifier 13.

During the sensing, signal line bSAEQ is low, and signal line SAN is high. The power supply line VSAEQ and signal line SAP are fixed at high. Moreover, voltages that respectively clamp the bit line BL and the bit line bBL to a read voltage and the reference voltage are set for signal line VBLCP and signal line VbBLCP that control the column gate. The word line WL to which the memory cell MC is connected and the word line RWL to which the corresponding reference cell RC is connected are made high. At the same time, a read current runs through the memory cell MC connected to the bit line BL, and the reference current runs through the reference cell RC connected to the bit line bBL.

The resistance of the reference cell RC is fixed to the low-resistance state or the high-resistance state. The reference current is set to be a current between the read current for the low-resistance memory cell and the read current for the high-resistance memory cell. After the start of the sensing, signal line bSAEQ is made high and signal line SAN is made low, such that the sense amplifier 13 retains data based on the intensities of the read current and the reference current. After this condition is produced, signal line VBLCP and signal line VbBLCP are made low to prevent a current from running through the memory cell MC or the reference cell RC.

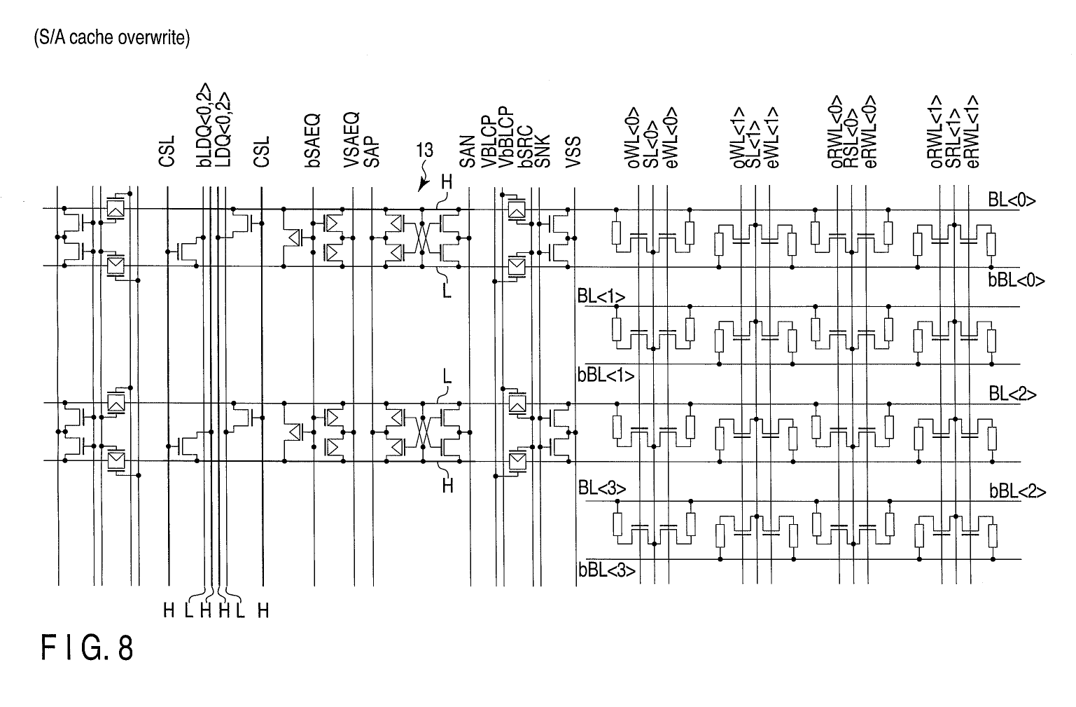

FIG. 8 is a circuit diagram showing the behavior of the S/A cache overwrite. Signal line CSL corresponding to the particular sense amplifier 13 is made high, such that the sense amplifier 13 is connected to the complementary data lines LDQ and bLDQ, and the data retained in the sense amplifier 13 is overwritten on the basis of the data supplied to these data lines. At the same time, the sense amplifier 13 corresponding to the memory cell in which no writing is performed is not overwritten. That is, the read data remains retained in this sense amplifier.

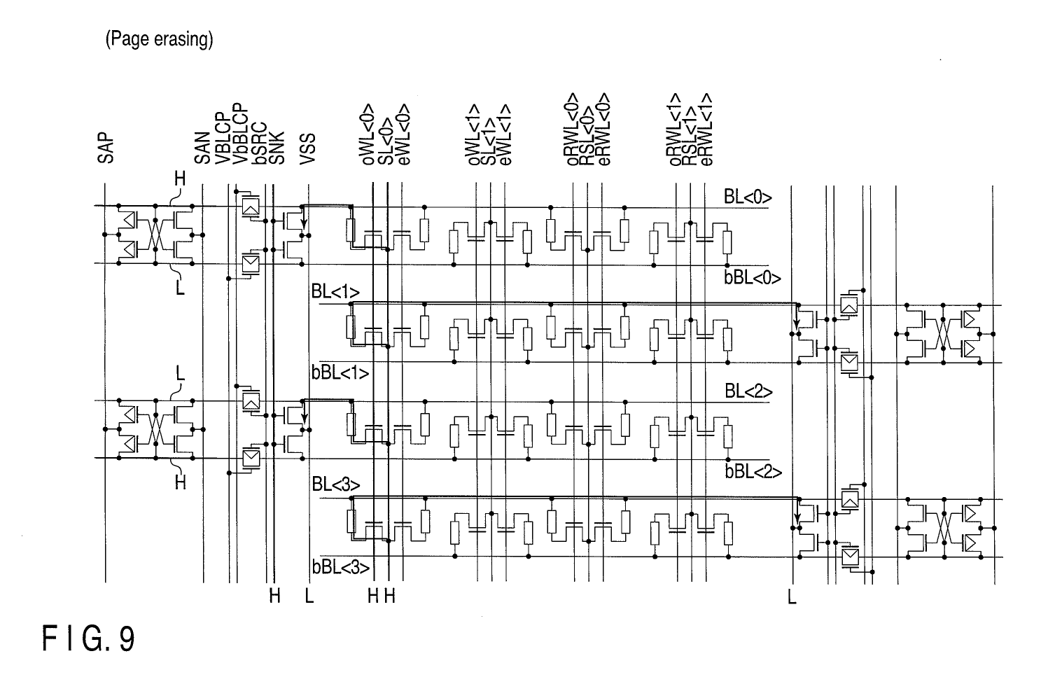

FIG. 9 is a circuit diagram showing the behavior of the page erasing. The page erasing is performed collectively for all of the memory cells MC that constitute a page. Specifically, signal line SNK is made high, and the source lines SL connected to the memory cells MC that constitute the page are made high. Thus, an erase current is generated in a direction from the source line SL to the bit line BL, and the resistance state of all of the memory cells MC that constitute the page is changed to the low-resistance state.

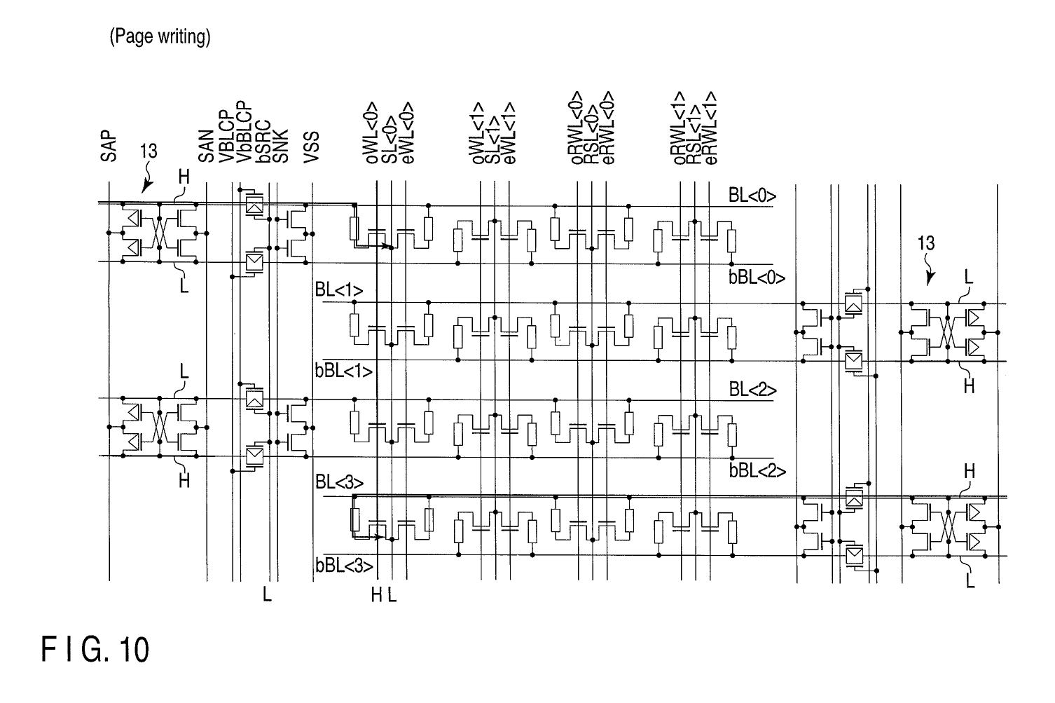

FIG. 10 is a circuit diagram showing the behavior of the page writing. The page writing is only performed in the memory cell MC that requires writing, in accordance with the write data retained in the sense amplifier 13. Specifically, signal line bSRC is made low, and the source lines SL connected to the memory cells MC that constitute a page are made low. Thus, a write current is generated in a direction from the bit line BL to the source line SL in accordance with the write data in the sense amplifier 13, and the resistance state of the particular memory cell is changed to the high-resistance state.

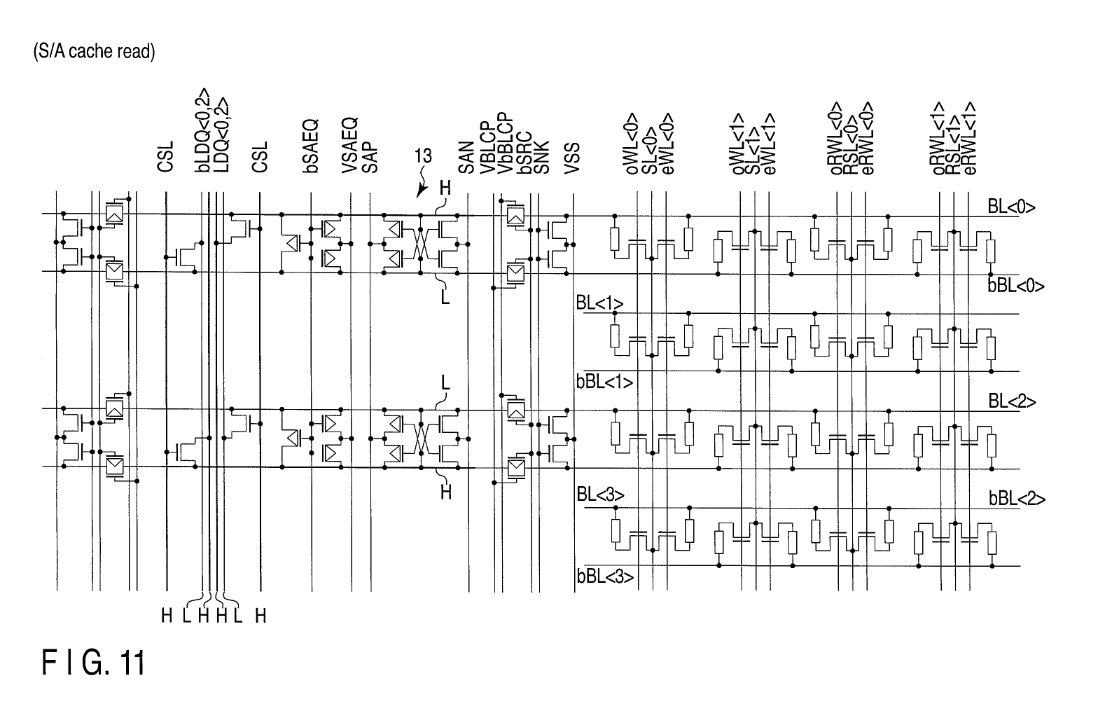

FIG. 11 is a circuit diagram showing the behavior of the S/A cache read. Signal line CSL corresponding to the particular sense amplifier 13 is made high, such that the sense amplifier 13 is connected to the complementary data lines LDQ and bLDQ. Thus, the data retained in the sense amplifier 13 is transferred to the peripheral circuit component via the data lines LDQ and bLDQ.

In the MRAM which has the circuit configuration described above and which has the write sequence and the read sequence, data can be erased collectively in the memory cells connected to the same word line (page) simply by changing the source line to an erase voltage (high in the example described above). Consequently, rapid write operation can be performed, and power consumption during erasing can be reduced.

According to the first embodiment, even if bi-directional currents need to be passed through the memory cell to control the resistance state of the memory cell, rapid write operation and read operation can be performed in the memory cells constituting a page. That is, a page access mode highly compatible with a DRAM can be provided.

### [2] Second Embodiment

An MRAM according to the second embodiment is described below.

In a circuit configuration according to the second embodiment, the bit line BL and the bit line bBL connected to the sense amplifier in the first embodiment are arranged in different cell arrays.

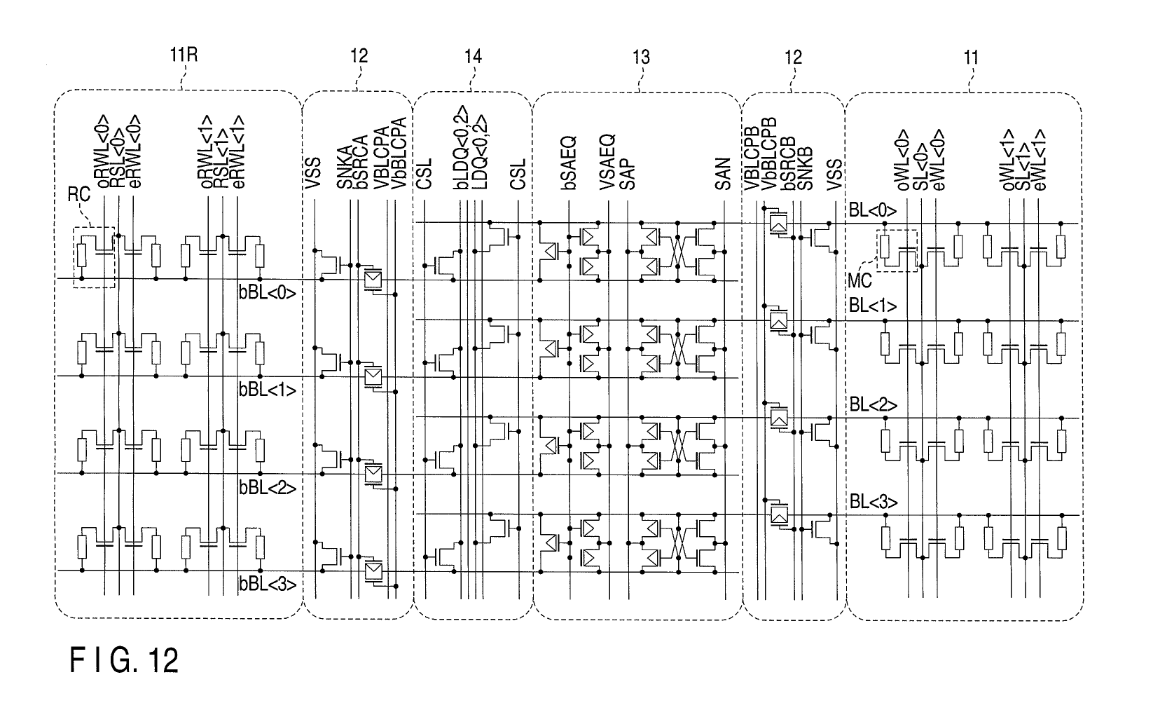

FIG. 12 is a circuit diagram showing the configuration of the MRAM according to the second embodiment.

A cell array 11 is disposed on one side of the sense amplifier 13 via a column gate and bit line clamper 12. A cell array 11R is disposed on the other side of the sense amplifier 13 via a column selection switch and data line 14 and a column gate and bit line clamper 12. Memory cells MC are arranged in matrix form in the cell array 11. Reference cells RC are arranged in matrix form in the cell array 11R.

According to the second embodiment having such a circuit configuration, a write sequence and a read sequence can be performed as in the first embodiment. The second embodiment is similar in configuration and advantages to the previously described first embodiment in other respects.

[3] Advantages of Embodiments

According to the embodiments described above, in the memory cell array in which the bit lines and the source lines intersect at right angles, data can be erased collectively in the memory cells connected to the same word line (the memory cells that constitute a page) simply by changing the source line to the erase voltage (high in the example described above). Consequently, easy and rapid write operation can be performed as in a DRAM, and power consumption during erasing can be reduced.

Furthermore, according to the embodiments, the memory cell array in which the bit lines and the source lines intersect at right angles is provided. Thus, the memory cell array can be smaller than a memory cell array in which bit lines and source lines are parallel.

As described above, according to the embodiments, even if bi-directional currents need to be passed through the memory cell to control the resistance state of the memory cell, rapid write operation and read operation can be performed in the memory cells constituting a page. That is, a page access mode highly compatible with a DRAM can be provided. Moreover, the memory cell array in which the bit lines and the source lines intersect at right angles is provided. Thus, the memory cell array can be easily made smaller than a memory cell array in which bit lines and source lines are parallel.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a cell array comprising memory cells, one end of each of the memory cells being connected to each of first bit lines, the other end of each of the memory cells being connected to a first source line, a gate terminal of each of the memory cells being connected to a word line; and
sense amplifiers connected to the first bit lines, the sense amplifiers reading the memory cells and retaining data,
wherein first writing changes the resistance of the memory cells connected to the word line to a first state by a current running from the first source line to the first bit lines,
second writing changes the resistance of the memory cells to a second state by a current running from the first bit lines to the first source line on the basis of data retained by the sense amplifiers after the first writing, and
before the first writing, data is read from the memory cells, and the read data is retained in the sense amplifiers, and the data retained by the sense amplifiers is overwritten in accordance with write data.

2. The semiconductor memory device according to claim 1, wherein
the gate terminals of the memory cells are connected to the word line, and the memory cells constitute a page,
the first source line extends in a direction to intersect with the first bit lines, and the other ends of the memory cells are connected to the first source line, and
the first writing is performed collectively for the memory cells constituting the page by supplying a write voltage to the first source line.

3. The semiconductor memory device according to claim 1, further comprising reference cells,
wherein one end of each of the reference cells is connected to each of the first bit lines, and the other end of each of the reference cells is connected to a second source line.

4. The semiconductor memory device according to claim 1, further comprising reference cells,
wherein one end of each of the reference cells is connected to each of second bit lines, and the other end of each of the reference cells is connected to a second source line, and
the sense amplifiers are connected to the second bit lines.

5. The semiconductor memory device according to claim 1, wherein
each of the sense amplifiers comprises a first n-channel MOS transistor and a first p-channel MOS transistor, and a second n-channel MOS transistor and a second p-channel MOS transistor, the first n-channel MOS transistor and the first p-channel MOS transistor comprising drain terminals connected to the first bit line and gate terminals connected to the second bit line, the second n-channel MOS transistor and the second p-channel MOS transistor comprising drain terminals connected to the second bit line and gate terminals connected to the first bit line.

6. The semiconductor memory device according to claim 1, wherein
the current running in the first writing changes the memory cells to low resistance, the current running in the second writing changes the memory cells to high resistance, and the current running in the reading is in the same direction as the current running in the second writing.

7. The semiconductor memory device according to claim 1, wherein
each of the memory cells comprises a first variable resistance element and a first select transistor.

8. The semiconductor memory device according to claim 7, wherein
one end of the first variable resistance element is connected to the first bit line, the other end of the first variable resistance element is connected to one end of a current path of the first select transistor, and the other end of the current path of the first select transistor is connected to the first source line.

9. The semiconductor memory device according to claim 7, wherein
the first variable resistance element includes a magnetoresistive element.

10. The semiconductor memory device according to claim 3, wherein
each of the memory cells comprises a first variable resistance element and a first select transistor, and each of the reference cells comprises a second variable resistance element and a second select transistor.

11. The semiconductor memory device according to claim 10, wherein
one end of the first variable resistance element is connected to the first bit line, the other end of the first variable resistance element is connected to one end of a current path of the first select transistor, and the other end of the current path of the first select transistor is connected to the first source line, and
one end of the second variable resistance element is connected to the first bit line, the other end of the second variable resistance element is connected to one end of a current path of the second select transistor, and the other end of the current path of the second select transistor is connected to the second source line.

12. The semiconductor memory device according to claim 10, wherein
the first variable resistance element and the second variable resistance element include magnetoresistive elements, respectively.

13. The semiconductor memory device according to claim 4, wherein
each of the memory cells comprises a first variable resistance element and a first select transistor, and each of the reference cells comprises a second variable resistance element and a second select transistor.

14. The semiconductor memory device according to claim 13, wherein
one end of the first variable resistance element is connected to the first bit line, the other end of the first variable resistance element is connected to one end of a current path of the first select transistor, and the other end of the current path of the first select transistor is connected to the first source line, and
one end of the second variable resistance element is connected to the second bit line, the other end of the second variable resistance element is connected to one end of a current path of the second select transistor, and the other end of the current path of the second select transistor is connected to the second source line.

15. The semiconductor memory device according to claim 13, wherein
the first variable resistance element and the second variable resistance element include magnetoresistive elements, respectively.

16. The semiconductor memory device according to claim 1, wherein
The first state has the resistance lower than that of the second state.

17. The semiconductor memory device according to claim 1, wherein
the first state corresponds to data “0” and the second state corresponds to data “1”.
